(19) United States
(12) Patent Application Publication
(10) Pub. No.: US 2007/0102760 A1
(43) Pub. Date: May 10, 2007

(54) Inhibiting radiation hardness of integrated circuits

(75) Inventor: David O. Erstad, Minnetonka, MN (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell International Inc., Morristown, NJ (US)

(21) Appl. No.: 11/271,654

(22) Filed: Nov. 10, 2005

(51) Int. Cl. H01L 27/12; H01L 27/01

(52) U.S. Cl. 257/347; 257/349; 257/E21.563

(57) ABSTRACT

A system and method for inhibiting radiation hardness of Silicon on Insulator (SOI) integrated circuits is described. An electrical connection is used to connect a substrate below a buried oxide layer to the topside above the buried oxide layer. A bias is then applied to the substrate. The bias may turn on a parasitic backgate in the buried oxide layer. As a result, the integrated circuit may not meet certain hardness criteria and, thus, not be subject to certain export restrictions imposed by the International Traffic in Arms Regulations.

### FIELD

The present invention relates generally to integrated circuits, and more specifically to inhibiting radiation hardness of integrated circuits.

### BACKGROUND

Radiation hardened integrated circuits have utility for several purposes, most notably for space-based electronic systems or military electronic systems that may be exposed to natural and/or man-made radiation events. Because of the importance of radiation hardened integrated circuits to national security, the United States Government imposes restrictions on radiation hardened integrated circuits. The International Traffic in Arms Regulations (ITAR, 22 CFR 120-130) defines certain classes of integrated circuits as United States Military List (USML) items under Category XV—Space Systems and Associated Equipment. An integrated circuit that meets or exceeds five specific characteristics is automatically considered as USML equipment.

Silicon On Insulator (SOI) technology may inherently meet the five hardness characteristics and, as a result, automatically be considered as USML equipment. Thus, integrated circuits built on this technology may be classified as USML equipment even though the intended end use is for a non-radiation environment. Such a classification, and the associated export restrictions, could be a significant impediment to the commercial viability of the technology. Accordingly, it would be desirable to have a method to inhibit the radiation hardness characteristics of SOI technology. Because the ITAR restrictions require that an integrated circuit meet all five hardness criteria, it is sufficient to inhibit any one of the five hardness criteria. One of the five criteria is a total dose hardness of 5×10⁵ Rads (Si), which means that the integrated circuit is immune to ionizing radiation doses up to the indicated level.

Ionizing radiation has a number of effects on SOI integrated circuits. One of these effects is to reduce the threshold voltage of a “backgate” formed by the buried oxide. If the threshold voltage of a transistor's backgate reduces significantly, the transistor may become conductive even when the transistor's “front gate” (i.e., the normal gate) is attempting to turn the transistor off. This may lead to excessive leakage and/or functional failure.

However, by reducing the threshold voltage of a transistor's backgate, the transistor may not meet the total dose hardness criteria. Beneficially, the transistor may be used in a non-radiation environment and avoid certain export restrictions on radiation hardened integrated circuits.

### SUMMARY

A system and method for inhibiting the total dose radiation hardness of an SOI integrated circuit is described. Generally, an electrical connection is made to the backside of an SOI die. In one example, the electrical connection is made with topside contacts forming an electrical connection from a portion of the die containing active circuitry to a substrate. In another example, the electrical connection is made via packaging.

More specifically, an SOI integrated circuit includes an active region containing transistors, a substrate, and a buried oxide. The buried oxide is located substantially between the active region and the substrate. The SOI integrated circuit also includes an electrical connection between the active region and the substrate that produces a bias on the substrate. The bias inhibits radiation hardness.

The electrical connection may be provided by at least one topside contact. Alternatively or additionally, the electrical connection may be provided by a connection through a package.

In one example, the bias on the substrate may be generated by a supply voltage used on the integrated circuit. In another example, the bias on the substrate may be generated by circuitry on the integrated circuit. In yet another example, the bias on the substrate may be generated by a voltage present in a system that is connected to the substrate.

A method for inhibiting radiation hardness of an SOI integrated circuit includes applying a bias voltage to a substrate. The bias voltage causes a parasitic backgate to be formed in a buried oxide layer. Applying a bias voltage may include forming an electrical connection from at least one topside contact to the substrate. The at least one topside contact may be connected to a voltage source. In one example, the voltage source may be a supply voltage used on the integrated circuit. In another example, the voltage source is generated by circuitry on the integrated circuit. In yet another example, the voltage source is a voltage present in a system that is connected to the substrate.

Alternatively or additionally, applying a bias voltage includes forming an electrical connection from a package that holds the integrated circuit to the substrate. At least one trace in the package may be connected to a voltage source. In one example, the voltage source may be a supply voltage used on the integrated circuit. In another example, the voltage source is generated by circuitry on the integrated circuit. In yet another example, the voltage source is a voltage present in a system that is connected to the substrate.

The electrical connection is used to bias the substrate to a voltage level. Biasing the substrate to a positive voltage relative to the topside has two deleterious effects on radiation hardness. First, this bias configuration accelerates the radiation-induced trapping of positive charge in the buried oxide, which has the effect of accelerating the threshold voltage decline. Second, by providing a positive bias to the substrate, the backgate turns on more readily.

These as well as other aspects and advantages will become apparent to those of ordinary skill in the art by reading the following detailed description, with reference where appropriate to the accompanying drawings. Further, it is understood that this summary is merely an example and is not intended to limit the scope of the invention as claimed.

### BRIEF DESCRIPTION OF THE DRAWINGS

Presently preferred embodiments are described below in conjunction with the appended drawing figures, wherein like reference numerals refer to like elements in the various figures, and wherein:

FIG. 1 is a cross-sectional view of an SOI transistor;

FIG. 2 is a plan view of an SOI die, according to an example; and

FIG. 3 is a pictorial representation of an SOI integrated circuit located in a package, according to an example.

### DETAILED DESCRIPTION

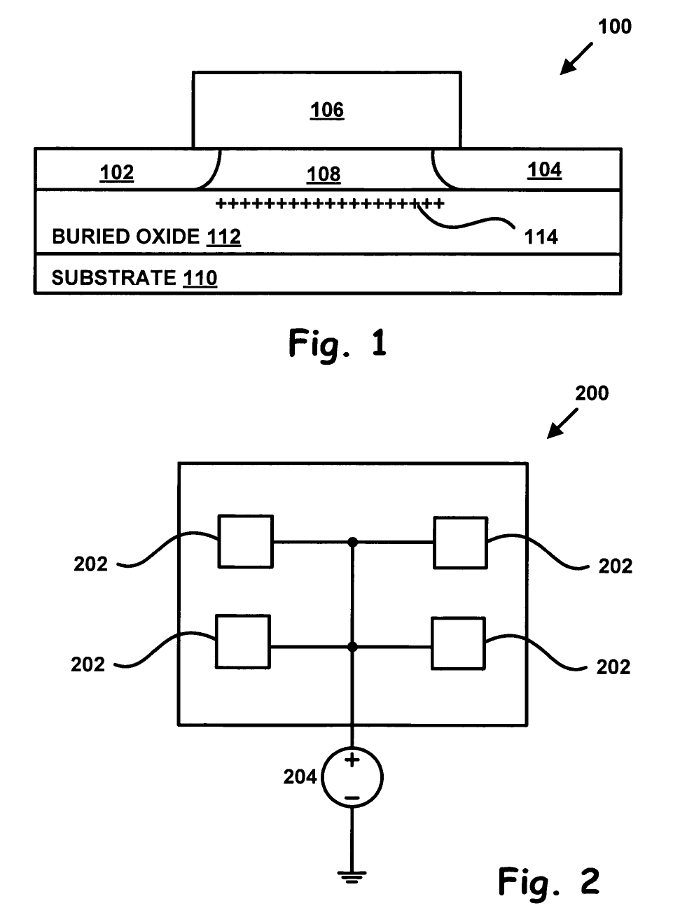

FIG. 1 shows a cross-sectional view of an SOI transistor 100. The transistor 100 consists of a source 102, a drain 104, a gate 106, a channel 108, a substrate 110, and buried oxide 112 according to established principles. If the transistor 100 is an NMOS transistor, the source 102 and the drain 104 are formed from an N-type semiconductor, and the channel 108 is formed from a P-type semiconductor. If the transistor 100 is a PMOS transistor, the source 102 and the drain 104 are formed from a P-type semiconductor, and the channel 108 is formed from a N-type semiconductor.

The operation of an NMOS transistor is described as follows. When no bias is applied to the gate 106, current is inhibited from flowing from the drain 104 to the source 102. When a positive bias is applied to the gate 106, a conductive region is formed in the channel 108 and current is enabled to flow from the drain 104 to the source 102. A PMOS transistor operates similarly except that when a negative bias is applied to the gate 106, current flows from the source 102 to the drain 104.

In addition to this normal and desirable operation, the buried oxide 112 may form a parasitic and undesirable gate 114 (referred to as a “backgate”), which is also capable of controlling the channel 108. The threshold voltage of the backgate 114 is normally quite high. For example, a value for the backgate threshold might be 30V, although other threshold voltages are possible. In typical SOI usage, the substrate 110 is either grounded or floating. Thus, a substrate voltage large enough to turn on the backgate 114 sufficiently to cause significant conduction typically does not develop.

When subjected to ionizing radiation, positive charge collects in the buried oxide 112. This positive charge decreases the threshold voltage of the backgate 114. However, as long as the threshold voltage of the backgate 114 remains sufficiently large, no deleterious effects will occur.

FIG. 2 shows a plan view of an SOI die 200. The die 200 is assumed to be covered with integrated circuits, which are not explicitly shown in FIG. 2. Fabricating integrated circuits on a die is well-known in the art. A plurality of topside contacts 202 is located on the die 200. FIG. 2 depicts four contacts 202, but it is understood that the die 200 may have more or less than four contacts 202. The topside contacts 202 represent a connection point between the top side of the die 200 (the region above the buried oxide 112 in FIG. 1) and the substrate 110 of the die 200 (the region below the buried oxide 112 in FIG. 1).

The topside contacts 202 are connected to a voltage source 204. The voltage source 204 provides a voltage that is more positive than at least one other voltage present on the topside of the die 200. The voltage source may provide the highest voltage present on the die 200. However, this is not necessary.

The topside contacts 202 may be connected to the die's positive power supply (typically referred to as “VDD”). As another example, the topside contacts 202 may be connected to any voltage present in a system that is connected to the substrate 110. As yet another example, circuitry may be present on the die 200 that creates a positive 20 voltage, which is then connected to the substrate 110. Charge pump circuitry, for example, may be used to bias the substrate 110 to a higher voltage than the supply voltage.

The presence of the positive voltage on the substrate 110 may accelerate the trapping of positive charge in the buried oxide 112. Additionally, the presence of a positive voltage on the substrate 110 may produce a bias to the backgate 114, reducing the threshold voltage at which significant effects may be seen. By reducing the threshold voltage, the integrated circuits on the die 200 may not meet the total dose hardness criteria.

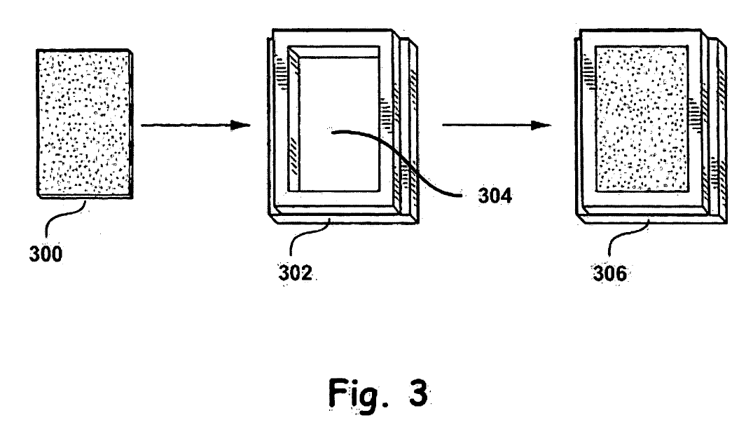

FIG. 3 shows a method of making an electrical connection from the portion of a die 300 containing active circuitry to the backside. In this example, the electrical connection is made via packaging. The integrated circuit die 300 is inserted into a package 302 to form an assembly 306. The package 302 has a cavity floor 304, which is connected to an appropriate voltage bias by traces internal to the package 302. The voltage bias may be the die's positive power supply (“VDD”), any other voltage present in the system, or other circuitry that generates a positive voltage.

By making an electrical connection to bias the substrate 110, the integrated circuit may be prevented from meeting the total dose radiation hardness criteria. The bias voltage applied to the substrate 110 accelerates the radiation-induced trapping of positive charge in the buried oxide 112, which has the effect of accelerating the threshold voltage decline. Additionally, the backgate 114 turns on more readily. Thus, the integrated circuit may be used in a non-radiation environment and avoid certain export restrictions on radiation hardened integrated circuits.

It should be understood that the illustrated embodiments are examples only and should not be taken as limiting the scope of the present invention. The claims should not be read as limited to the described order or elements unless stated to that effect. Therefore, all embodiments that come within the scope and spirit of the following claims and equivalents thereto are claimed as the invention.

I claim:

1. A Silicon on Insulator integrated circuit, comprising in combination:
an active region containing transistors;
a substrate;
a buried oxide located substantially between the active region and the substrate; and
an electrical connection between the active region and the substrate that produces a bias on the substrate, wherein the bias inhibits radiation hardness.

2. The circuit of claim 1, wherein the electrical connection is provided by at least one topside contact.

3. The circuit of claim 1, wherein the electrical connection is provided by a connection through a package.

4. The circuit of claim 1, wherein the bias on the substrate is generated by a supply voltage used on the integrated circuit.

5. The circuit of claim 1, wherein the bias on the substrate is generated by circuitry on the integrated circuit.

6. The circuit of claim 1, wherein the bias on the substrate is generated by a voltage present in a system that is connected to the substrate.

7. A method for inhibiting radiation hardness of a Silicon on Insulator integrated circuit, comprising applying a bias voltage to a substrate, wherein the bias voltage causes a parasitic backgate to be formed in a buried oxide layer.

8. The method of claim 7, wherein applying a bias voltage includes forming an electrical connection from at least one topside contact to the substrate.

9. The method of claim 8, wherein applying a bias voltage includes connecting the at least one topside contact to a voltage source.

10. The method of claim 9, wherein the voltage source is a supply voltage used on the integrated circuit.

11. The method of claim 9, wherein the voltage source is generated by circuitry on the integrated circuit.

12. The method of claim 9, wherein the voltage source is a voltage present in a system that is connected to the substrate.

13. The method of claim 7, wherein applying a bias voltage includes forming an electrical connection from a package that holds the integrated circuit to the substrate.

14. The method of claim 13, wherein applying a bias voltage includes connecting at least one trace in the package to a voltage source.

15. The method of claim 14, wherein the voltage source is a supply voltage used on the integrated circuit.

16. The method of claim 14, wherein the voltage source is generated by circuitry on the integrated circuit.

17. The method of claim 14, wherein the voltage source is a voltage present in a system that is connected to the substrate.
